(19) United States
(12) Patent Application Publication
(10) Pub. No.: US 2017/0286218 A1
(43) Pub. Date: Oct. 5, 2017

(54) SEMICONDUCTOR DEVICES, AND SEMICONDUCTOR SYSTEMS

(71) Applicant: SK hynix Inc., Icheon-si Gyeonggi-do (KR)

(72) Inventor: Chang Hyun KIM, Seoul (KR)

(21) Appl. No.: 15/219,519

(22) Filed: Jul. 26, 2016

(30) Foreign Application Priority Data
Apr. 1, 2016 (KR) 10-2016-0039917

(51) Int. Cl. G06F 11/10; G06F 3/06; G11C 29/52

(52) U.S. Cl. CPC G06F 11/1068; G11C 29/52; G06F 3/0619; G06F 3/064; G06F 3/0679

(57) ABSTRACT

A write parity signal generation circuit, semiconductor device and semiconductor system may be provided. The write parity signal generation circuit may be configured to generate a pre-parity signal from a write data signal and a read data signal, and generate a write parity signal from the pre-parity signal and a syndrome signal.

### CROSS-REFERENCE TO RELATED APPLICATIONS

The present application claims priority under 35 U.S.C 119(a) to Korean Patent Application No. 10-2016-0039917, filed on Apr. 1, 2016, which is incorporated herein by reference in its entirety.

### BACKGROUND

### 1. Technical Field

Embodiments of the present disclosure may generally relate to semiconductor systems, and more particularly, to semiconductor systems including a write parity signal generation circuit.

### 2. Related Art

As semiconductor memory devices are scaled down and designed to operate at a high speed, errors occurring during a write operation and a read operation of the semiconductor memory devices may increase. An error check correction (ECC) circuit may be used to detect and correct the errors. The ECC circuit may generate parity signals of data signals which are written into the semiconductor memory device. The ECC circuit may correct errors of data signals which are read out according to the parity signals to output the corrected data signals.

### SUMMARY

According to an embodiment, a semiconductor device includes a write parity signal generation circuit and a data error correction circuit. The write parity signal generation circuit generates a pre-parity signal from a write data signal and a read data signal and also generates a write parity signal from the pre-parity signal and a syndrome signal in response to a control signal, if a mask write operation is performed. The data error correction circuit generates the syndrome signal from the read data signal and a read parity signal and also generates the control signal according to an error position of the read data signal included in the syndrome signal and a masked position of the write data signal included in an internal data mask signal.

According to another embodiment, a semiconductor device includes a memory core circuit and a write parity signal generation circuit. The memory core circuit generates a read data signal and a read parity signal from a storage region corresponding to an internal address signal in response to a write command signal and an internal data mask signal, if a mask write operation is performed. The write parity signal generation circuit generates a pre-parity signal from a write data signal and the read data signal and also generates a write parity signal from the pre-parity signal and a syndrome signal in response to a control signal, if the mask write operation is performed.

According to yet another embodiment, a semiconductor system includes a first semiconductor device and a second semiconductor device. The first semiconductor device is configured to outputs a command signal, an address signal and a data mask signal. In addition, the first semiconductor device is configured to receive or output a data signal. The second semiconductor device generates a read data signal and a read parity signal from a storage region corresponding to the address signal and receives the data signal to generate a write data signal, if a write command signal is generated in response to the command signal. In addition, the semiconductor device generates a pre-parity signal from the write data signal and the read data signal, generates a write parity signal from the pre-parity signal and a syndrome signal in response to a control signal, generates the syndrome signal from the read data signal and the read parity signal, and generates the control signal according to an error position of the read data signal and a masked position of the write data signal, if a mask write operation is performed in response to the data mask signal. The write data signal includes first and second write bit groups. The read data signal includes first and second read bit groups. The pre-parity signal is generated from the first write bit group and the second read bit group.

### BRIEF DESCRIPTION OF THE DRAWINGS

FIG. 1 is a block diagram illustrating a representation of an example of a configuration of a semiconductor system according to an embodiment of the present disclosure.

FIG. 2 is a block diagram illustrating a representation of an example of a pre-parity signal generation circuit included in the semiconductor system of FIG. 1.

FIG. 3 is a circuit diagram illustrating a representation of an example of a logic arithmetic circuit included in the semiconductor system of FIG. 1.

FIG. 4 is a block diagram illustrating a representation of an example of a data error correction circuit included in the semiconductor system of FIG. 1.

FIG. 5 is a block diagram illustrating a representation of an example of a memory core circuit included in the semiconductor system of FIG. 1.

FIG. 6 is a block diagram illustrating a representation of an example of a configuration of an electronic system employing the semiconductor system illustrated in FIG. 1 to FIG. 5.

### DETAILED DESCRIPTION

Various embodiments of the present disclosure will be described hereinafter with reference to the accompanying drawings. However, the embodiments described herein are for illustrative purposes only and are not intended to limit the scope of the present disclosure.

Various embodiments may be directed to semiconductor devices generating write parity signals for correction of errors during a mask write operation and semiconductor systems including the semiconductor devices.

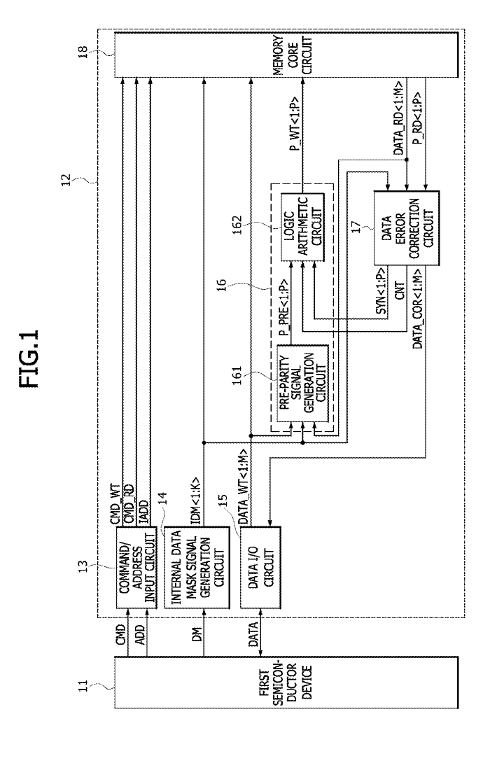

Referring to FIG. 1, a semiconductor system according to an embodiment of the present disclosure may include a first semiconductor device 11 and a second semiconductor device 12.

The first semiconductor device 11 may output a command signal CMD, an address signal ADD and a data mask signal DM and may receive or output a data signal DATA. The first semiconductor device 11 may output the command signal CMD to set an operation mode of the second semiconductor device 12. The command signal CMD may be configured to have a plurality of bits and may be set to have any one of various logic level combinations according to the operation mode of the second semiconductor device 12. The first semiconductor device 11 may output the address signal ADD for selecting at least one of memory cells included in the second semiconductor device 12. The command signal CMD and the address signal ADD may be transmitted through the same transmission line. The first semiconductor device 11 may output the data mask signal DM to mask some bits included in the data signal DATA. The data mask signal DM may have a plurality of bits to include information on a position of masked bits of the data signal DATA and the number of the bits of the data signal DATA. The first semiconductor device 11 may output the data signal DATA if a normal write operation or a mask write operation of the second semiconductor device 12 is performed. The first semiconductor device 11 may receive the data signal DATA if a read operation of the second semiconductor device 12 is performed.

The second semiconductor device 12 may include a command/address input circuit 13, an internal data mask signal generation circuit 14, a data input/output (input and output) (I/O) circuit 15, a write parity signal generation circuit 16, a data error correction circuit 17 and a memory core circuit 18.

The command/address input circuit 13 may receive the command signal CMD and the address signal ADD to output a write command signal CMD_WT, a read command signal CMD_RD and an internal address signal IADD. The command/address input circuit 13 may decode the command signal CMD to generate the write command signal CMD_WT or the read command signal CMD_RD. The command/address input circuit 13 may decode the address signal ADD to generate the internal address signal IADD. If the normal write operation or the mask write operation is performed, the command/address input circuit 13 may generate the write command signal CMD_WT in response to the command signal CMD. The normal write operation may be an operation that stores data of “M”-number of bits included in a write data signal DATA_WT<1:M> into the memory core circuit 18. The mask write operation may be an operation that stores only data of the remaining bits excluding bits masked according to an internal data mask signal IDM<1:M> from the “M”-number of bits included in the write data signal DATA_WT<1:M> into the memory core circuit 18. If the read operation is performed, the command/address input circuit 13 may generate the read command signal CMD_RD in response to the command signal CMD. The read operation may be an operation that outputs a read data signal DATA_RD<1:M> from the memory core circuit 18, corrects errors of the read data signal DATA_RD<1:M> to generate a correction data signal DATA_COR<1:M>, and outputs the correction data signal DATA_COR<1:M> as the data signal DATA.

The internal data mask signal generation circuit 14 may generate the internal data mask signal IDM<1:K> from the data mask signal DM. The internal data mask signal generation circuit 14 may buffer or decode the data mask signal DM to generate the internal data mask signal IDM<1:K>. If the mask write operation of the second semiconductor device 12 is performed, the internal data mask signal IDM<1:K> may include information on the position and the number of masked bits of the write data signal DATA_WT<1:M>.

The data I/O circuit 15 may buffer the data signal DATA to output the buffered signal as the write data signal DATA_WT<1:M> or may buffer the correction data signal DATA_COR<1:M> to output the buffered signal as the data signal DATA. If the normal write operation or the mask write operation of the second semiconductor device 12 is performed, the data I/O circuit 15 may buffer the data signal DATA to output the buffered data signal as the write data signal DATA_WT<1:M>. If the read operation of the second semiconductor device 12 is performed, the data I/O circuit 15 may buffer the correction data signal DATA_COR<1:M> to output the buffered correction data signal as the data signal DATA.

The write parity signal generation circuit 16 may include a pre-parity signal generation circuit 161 and a logic arithmetic circuit 162.

The pre-parity signal generation circuit 161 may generate a pre-parity signal P_PRE<1:P> from the read data signal DATA_RD<1:M> and the write data signal DATA_WT<1:M> in response to the internal data mask signal IDM<1:K>. If the mask write operation is performed, the pre-parity signal generation circuit 161 may generate the pre-parity signal P_PRE<1:P> from some bits of the write data signal DATA_WT<1:M> and some bits of the read data signal DATA_RD<1:M> in response to the internal data mask signal IDM<1:K>. The write data signal DATA_WT<1:M> may include a first write bit group and a second write bit group. If the mask write operation is performed, the first write bit group may include bits to be stored in the memory core circuit 18. If the mask write operation is performed, the second write bit group may include bits which are masked. The read data signal DATA_RD<1:M> may include a first read bit group and a second read bit group. The first read bit group may include bits which are outputted from a first storage region that stores the first write bit group, during the normal write operation or the mask write operation. The second read bit group may include bits which are outputted from a second storage region that stores the second write bit group, during the normal write operation. The pre-parity signal generation circuit 161 may generate the pre-parity signal P_PRE<1:P> from the first write bit group and the second read bit group. The pre-parity signal generation circuit 161 may perform an exclusive OR operation of two or more different bits among a plurality of bits included in the first write bit group and the second read bit group according to a Hamming code to generate the pre-parity signal P_PRE<1:P>. The pre-parity signal P_PRE<1:P> may include information on logic levels of the bits included in the first write bit group and the second read bit group.

The logic arithmetic circuit 162 may generate a write parity signal P_WT<1:P> from the pre-parity signal P_PRE<1:P> and a syndrome signal SYN<1:P> in response to a control signal CNT. If the control signal CNT is enabled to have a logic high level, the logic arithmetic circuit 162 may perform an exclusive OR operation of the pre-parity signal P_PRE<1:P> and the syndrome signal SYN<1:P> to generate the write parity signal P_WT<1:P>. If the control signal CNT is disabled to have a logic low level, the logic arithmetic circuit 162 may buffer the pre-parity signal P_PRE<1:P> to generate the write parity signal P_WT<1:P>. Further, the logic levels of the signals may be different from or the opposite of those described. For example, a signal described as having a logic “high” level may alternatively have a logic “low” level, and a signal described as having a logic “low” level may alternatively have a logic “high” level.

The data error correction circuit 17 may receive the read data signal DATA_RD<1:M>, a read parity signal P_RD<1:P> and the internal data mask signal IDM<1:K> to generate the syndrome signal SYN<1:P>, the control signal CNT and the correction data signal DATA_COR<1:M>. The data error correction circuit 17 may generate the syndrome signal SYN<1:P> from the read data signal DATA_RD<1:M> and the read parity signal P_RD<1:P>. The syndrome signal SYN<1:P> may include information on a position of erroneous bits of the read data signal DATA_RD<1:M>. The data error correction circuit 17 may generate the control signal CNT in response to the internal data mask signal IDM<1:K> and the syndrome signal SYN<1:P>. The data error correction circuit 17 may compare positions of masked bits of the write data signal DATA_WT<1:M> included in the internal data mask signal IDM<1:K> with positions of erroneous bits of the read data signal

DATA_RD<1:M> included in the syndrome signal SYN<1:P> to generate the control signal CNT. If the positions of the erroneous bits of the read data signal DATA_RD<1:M> are identical to the positions of the masked bits of the write data signal DATA_WT<1:M>, the data error correction circuit 17 may generate the control signal CNT which is enabled to have a logic high level. If the positions of the erroneous bits of the read data signal DATA_RD<1:M> are different from the positions of the masked bits of the write data signal DATA_WT<1:M>, the data error correction circuit 17 may generate the control signal CNT which is disabled to have a logic low level. If the read operation of the second semiconductor device 12 is performed, the data error correction circuit 17 may correct the error of the read data signal DATA_RD<1:M> to generate the correction data signal DATA_COR<1:M> in response to the syndrome signal SYN<1:P>. Further, the logic levels of the signals may be different from or the opposite of those described. For example, a signal described as having a logic “high” level may alternatively have a logic “low” level, and a signal described as having a logic “low” level may alternatively have a logic “high” level.

The memory core circuit 18 may store the write data signal DATA_WT<1:M> and the write parity signal P_WT<1:P> therein or may output the read data signal DATA_RD<1:M> and the read parity signal P_RD<1:P>, in response to the write command signal CMD_WT, the read command signal CMD_RD, the internal address signal IADD and the internal data mask signal IDM<1:K>. If the normal write operation is performed, the memory core circuit 18 may store the write data signal DATA_WT<1:M> and the write parity signal P_WT<1:P> in a storage region corresponding to the internal address signal IADD in response to the write command signal CMD_WT and the internal data mask signal IDM<1:K>. If the mask write operation is performed, the memory core circuit 18 may output the read data signal DATA_RD<1:M> and the read parity signal P_RD<1:P> from the storage region corresponding to the internal address signal IADD and may then store the write data signal DATA_WT<1:M> and the write parity signal P_WT<1:P> in memory cells corresponding to the internal address signal IADD after a predetermined period, in response to the write command signal CMD_WT and the internal data mask signal IDM<1:K>. The predetermined period may be set to be a time period from a point of time that the read data signal DATA_RD<1:M> and the read parity signal P_RD<1:P> are outputted from the memory core circuit 18 till a point of time that the write parity signal P_WT<1:P> is generated by the write parity signal generation circuit 16. If the read operation is performed, the memory core circuit 18 may output the read data signal DATA_RD<1:M> and the read parity signal P_RD<1:P> from the storage region corresponding to the internal address signal IADD in response to the read command signal CMD_RD.

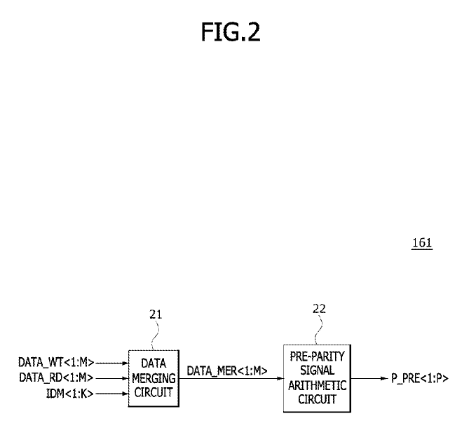

Referring to FIG. 2, the pre-parity signal generation circuit 161 may include a data merging circuit 21 and a pre-parity signal arithmetic circuit 22.

The data merging circuit 21 may generate a merging data signal DATA_MER<1:M> from the write data signal DATA_WT<1:M> and the read data signal DATA_RD<1:M> in response to the internal data mask signal IDM<1:K>. The data merging circuit 21 may generate the merging data signal DATA_MER<1:M> from some bits of the write data signal DATA_WT<1:M> and some bits of the read data signal DATA_RD<1:M> according to the internal data mask signal IDM<1:K>.

For example, the write data signal DATA_WT<1:M> may include a first write bit group and a second write bit group. If the bits included in first to N^{th} write data signals DATA_WT<1:N> among the first to M^{th} write data signals DATA_WT<1:M> are masked in response to the internal data mask signal IDM<1:K>, the first write bit group may include the bits in the (N+1)^{th} to M^{th} write data signals DATA_WT<N+1:M> and the second write bit group may include the bits in the first to N^{th} write data signals DATA_WT<1:N>. If the bits included in the N^{th} to M^{th} write data signals DATA_WT<N:M> among the first to M^{th} write data signals DATA_WT<1:M> are masked in response to the internal data mask signal IDM<1:K>, the first write bit group may include the bits in the first to (N−1)^{th} write data signals DATA_WT<1:N−1> and the second write bit group may include the bits in the N^{th} to M^{th} write data signals DATA_WT<N:M>. If the bits included in the N^{th} to L^{th} write data signals DATA_WT<N:L> among the first to M^{th} write data signals DATA_WT<1:M> are masked in response to the internal data mask signal IDM<1:K>, the first write bit group may include the bits in the first to (N−1)^{th} write data signals DATA_WT<1:N−1> and the (L+1)^{th} to M^{th} write data signals DATA_WT<L+1:M>, and the second write bit group may include the bits in the N^{th} to L^{th} write data signals DATA_WT<N:L>. “N” and “L” may be set to be natural numbers which are less than “M”, and “N” may be set to be a natural number which is less than “L”.

The read data signal DATA_RD<1:M> may include a first read bit group and a second read bit group. The first read bit group may include bits outputted from the first storage region that stores the first write bit group. If the first write bit group includes the bits of the (N+1)^{th} to M^{th} write data signals DATA_WT<N+1:M>, the first read bit group may include the bits of the (N+1)^{th} to M^{th} read data signals DATA_RD<N+1:M>. If the first write bit group includes the bits of the first to (N−1)^{th} write data signals DATA_WT<1:N−1>, the first read bit group may include the bits of the first to (N−1)^{th} read data signals DATA_RD<1:N−1>. If the first write bit group includes the bits of the first to (N−1)^{th} write data signals DATA_WT<1:N−1> and the (L+1)^{th} to M^{th} write data signals DATA_WT<L+1:M>, the first read bit group may include the bits of the first to (N−1)^{th} read data signals DATA_RD<1:N−1> and the (L+1)^{th} to M^{th} read data signals DATA_RD<L+1:M>. The second read bit group may include the bits outputted from the second storage region that stores the second write bit group. If the second write bit group includes the bits of the first to N^{th} write data signals DATA_WT<1:N>, the second read bit group may include the bits of the first to N^{th} read data signals DATA_RD<1:N>. If the second write bit group includes the bits of the N^{th} to M^{th} write data signals DATA_WT<N:M>, the second read bit group may include the bits of the N^{th} to M^{th} read data signals DATA_RD<N:M>. If the second write bit group includes the bits of the N^{th} to L^{th} write data signals DATA_WT<N:L>, the second read bit group may include the bits of the N^{th} to L^{th} read data signals DATA_RD<N:L>.

The data merging circuit 21 may generate the merging data signal DATA_MER<1:M> from the first write bit group included in the write data signal DATA_WT<1:M> and the second read bit group included in the read data signal DATA_RD<1:M> in response to the internal data mask signal IDM<1:K>. If the first write bit group includes the bits of the (N+1)^{th} to M^{th} write data signals DATA_WT<N+1:M> and the second read bit group includes the bits of the first to N^{th} read data signals DATA_RD<1:N>, the data merging circuit 21 may generate the first to M^{th} merging data signals DATA_MER<1:M> from the first to N^{th} read data signals DATA_RD<1:N> and the (N+1)^{th} to M^{th} write data signals DATA_WT<N+1:M>. If the first write bit group includes the bits of the first to (N−1)^{th} write data signals DATA_WT<1:N−1> and the second read bit group includes the bits of the N^{th} to M^{th} read data signals DATA_RD<N:M>, the data merging circuit 21 may generate the first to M^{th} merging data signals DATA_MER<1:M> from the first to (N−1)^{th} write data signals DATA_WT<1:N−1> and the N^{th} to M^{th} read data signals DATA_RD<N:M>. If the first write bit group includes the bits of the first to (N−1)^{th} write data signals DATA_WT<1:N−1> and the (L+1)^{th} to M^{th} write data signals DATA_WT<L+1:M> and the second read bit group includes the bits of the N^{th} to L^{th} read data signals DATA_RD<N:L>, the data merging circuit 21 may generate the first to M^{th} merging data signals DATA_MER<1:M> from the first to (N−1)^{th} write data signals DATA_WT<1:N−1>, the N^{th} to L^{th} read data signals DATA_RD<N:L>, and the (L+1)^{th} to M^{th} write data signals DATA_WT<L+1:M>.

The pre-parity signal arithmetic circuit 22 may generate the pre-parity signal P_PRE<1:P> in response to the merging data signal DATA_MER<1:M>. The pre-parity signal arithmetic circuit 22 may generate the pre-parity signal P_PRE<1:P> including information on a logic level combination of the bits included in the merging data signal DATA_MER<1:M>. The pre-parity signal arithmetic circuit 22 may perform an exclusive OR operation of two or more different bits among the bits included in the merging data signal DATA_MER<1:M> to generate the pre-parity signal P_PRE<1:P>, according to the Hamming code. The pre-parity signal arithmetic circuit 22 may generate the pre-parity signal P_PRE<1:P> including the information on the logic level combination of the bits of the merging data signal DATA_MER<1:M>, using any one of various codes according to the embodiments. Further, the logic levels of the signals may be different from or the opposite of those described. For example, a signal described as having a logic “high” level may alternatively have a logic “low” level, and a signal described as having a logic “low” level may alternatively have a logic “high” level.

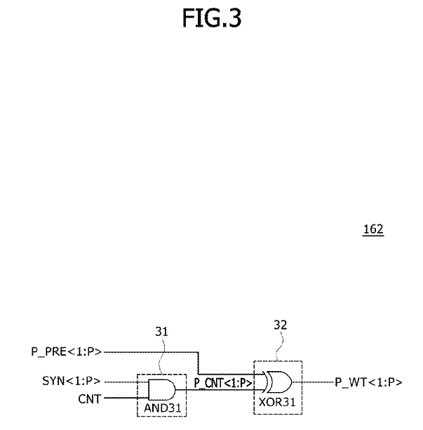

Referring to FIG. 3, the logic arithmetic circuit 162 may include a first logic circuit 31 and a second logic circuit 32.

The first logic circuit 31 may perform a logic operation. For example, the first logic circuit 31 may perform an AND logic operation and may include an AND gate AND31. The AND gate AND31 may perform an AND operation of the syndrome signal SYN<1:P> and the control signal CNT to generate a parity correction control signal P_CNT<1:P>. Although FIG. 3 illustrates only one AND gate AND31 included in the first logic circuit 31, the first logic circuit 31 may actually include the same number of AND gates as the bits of the syndrome signal SYN<1:P>. If the control signal CNT is enabled to have a logic high level, the first logic circuit 31 may buffer the syndrome signal SYN<1:P> to generate the parity correction control signal P_CNT<1:P>. If the control signal CNT is disabled to have a logic low level, the first logic circuit 31 may output the parity correction control signal P_CNT<1:P> having a logic low level. Further, the logic levels of the signals may be different from or the opposite of those described. For example, a signal described as having a logic “high” level may alternatively have a logic “low” level, and a signal described as having a logic “low” level may alternatively have a logic “high” level.

The second logic circuit 32 may perform a logic operation. For example, the second logic circuit 32 may perform an exclusive OR operation and may include an exclusive OR gate XOR31. The exclusive OR gate XOR31 may perform an exclusive OR operation of the pre-parity signal P_PRE<1:P> and the parity correction control signal P_CNT<1:P> to generate the write parity signal P_WT<1:P>. Although FIG. 3 illustrates only one exclusive OR gate XOR31 included in the second logic circuit 32, the second logic circuit 32 may actually include the same number of exclusive OR gates as the bits of the pre-parity signal P_PRE<1:P> or the parity correction control signal P_CNT<1:P> so that each of the bits of the write parity signal P_WT<1:P> is generated by the exclusive OR operation of the corresponding bit of the pre-parity signal P_PRE<1:P> and the corresponding bit of the parity correction control signal P_CNT<1:P>.

That is, the logic arithmetic circuit 162 may perform an exclusive OR operation of the pre-parity signal P_PRE<1:P> and the syndrome signal SYN<1:P> in response to the control signal CNT to generate the write parity signal P_WT<1:P>. The pre-parity signal generation circuit 161 may perform an exclusive OR operation of two or more different bits among the bits included in the first write bit group and the second read bit group to generate the pre-parity signal P_PRE<1:P>. If an erroneous bit exists in the bits included in the second read bit group, any one of the bits included in the pre-parity signal P_PRE<1:P> may have an erroneous logic level. If an erroneous bit exists in each of the first read bit group and the second read bit group included in the read data signal DATA_RD<1:M>, any one of the bits included in the syndrome signal SYN<1:P> may have a logic high level. Hence, if the second read bit group includes an erroneous bit, the logic arithmetic circuit 162 may perform an exclusive OR operation of the pre-parity signal P_PRE<1:P> and the syndrome signal SYN<1:P> to invert the bit of the pre-parity signal P_PRE<1:P> corresponding to the bit having a logic high level included in the syndrome signal SYN<1:P> and to generate the write parity signal P_WT<1:P>. Accordingly, the logic arithmetic circuit 162 may generate a normal write parity signal P_WT<1:P> by inverting the erroneous bit among the bits included in the pre-parity signal P_PRE<1:P>. Further, the logic levels of the signals may be different from or the opposite of those described. For example, a signal described as having a logic “high” level may alternatively have a logic “low” level, and a signal described as having a logic “low” level may alternatively have a logic “high” level.

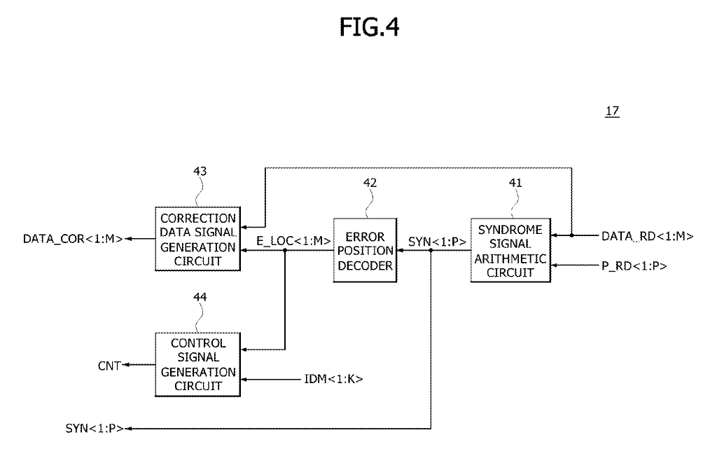

Referring to FIG. 4, the data error correction circuit 17 may include a syndrome signal arithmetic circuit 41, an error position decoder 42, a correction data signal generation circuit 43 and a control signal generation circuit 44.

The syndrome signal arithmetic circuit 41 may generate the syndrome signal SYN<1:P> in response to the read data signal DATA_RD<1:M> and the read parity signal P_RD<1:P>. The syndrome signal arithmetic circuit 41 may perform a predetermined arithmetic operation of the read data signal DATA_RD<1:M> and the read parity signal P_RD<1:P> to generate the syndrome signal SYN<1:P>. The syndrome signal arithmetic circuit 41 may perform an exclusive OR operation of two or more different bits among the bits included in the read data signal DATA_RD<1:M> and one bit among the bits included in the read parity signal P_RD<1:P> to generate the syndrome signal SYN<1:P> according to the Hamming code. The syndrome signal arithmetic circuit 41 may generate the syndrome signal SYN<1:P> using any one of various codes which is capable of performing an error correction operation, according to the embodiments. The syndrome signal SYN<1:P> may include information on a position of the erroneous bit among the bits included in the read data signal DATA_RD<1:M>.

The error position decoder 42 may decode the syndrome signal SYN<1:P> to generate an error position signal E_LOC<1:M>. A bit of the error position signal E_LOC<1:M> corresponding to the erroneous bit among the bits of the read data signal DATA_RD<1:M> may be enabled to have a logic high level. Further, the logic levels of the signals may be different from or the opposite of those described. For example, a signal described as having a logic “high” level may alternatively have a logic “low” level, and a signal described as having a logic “low” level may alternatively have a logic “high” level.

The correction data signal generation circuit 43 may correct an error of the read data signal DATA_RD<1:M> to generate the correction data signal DATA_COR<1:M> in response to the error position signal E_LOC<1:M>. The correction data signal generation circuit 43 may invert a bit among the bits of the read data signal DATA_RD<1:M> corresponding to the bit enabled to have a logic high level among the bits of the error position signal E_LOC<1:M> to generate the correction data signal DATA_COR<1:M>.

The control signal generation circuit 44 may generate the control signal CNT in response to the error position signal E_LOC<1:M> and the internal data mask signal IDM<1:K>. The control signal generation circuit 44 may compare the error position signal E_LOC<1:M> with the internal data mask signal IDM<1:K> to generate the control signal CNT which is enabled, if a position of the erroneous bit among the bits included in the read data signal DATA_RD<1:M> is identical to the position of the masked bit among the bits included in the write data signal DATA_WT<1:M>. For example, if the mask write operation is performed, the write data signal DATA_WT<1:M> may include the second write bit group which is masked according to the internal data mask signal IDM<1:K>. The read data signal DATA_RD<1:M> may include the second read bit group which is read out from the storage region that stores the second write bit group. Hence, if a position of the second read bit group is set according to the internal data mask signal IDM<1:K> and the second read bit group includes the erroneous bit according to the error position signal E_LOC<1:M>, the control signal generation circuit 44 may generate the control signal CNT which is enabled to have a logic high level. Further, the logic levels of the signals may be different from or the opposite of those described. For example, a signal described as having a logic “high” level may alternatively have a logic “low” level, and a signal described as having a logic “low” level may alternatively have a logic “high” level.

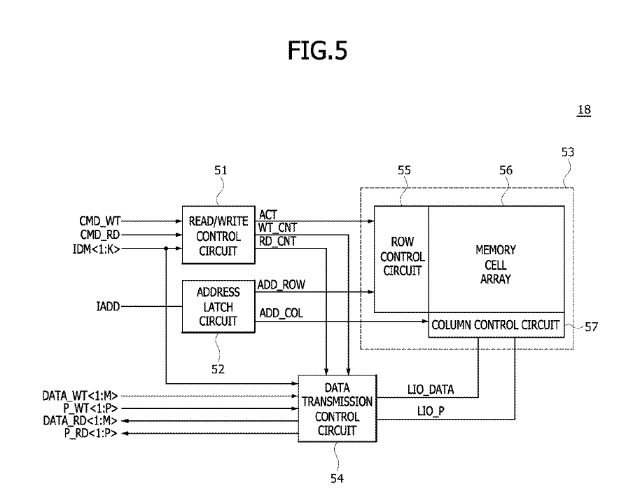

Referring to FIG. 5, the memory core circuit 18 may include a read/write control circuit 51, an address latch circuit 52, a memory bank 53 and a data transmission control circuit 54.

The read/write control circuit 51 may generate an active signal ACT, a write control signal WT_CNT and a read control signal RD_CNT in response to the write command signal CMD_WT, the read command signal CMD_RD and the internal data mask signal IDM<1:K>. If the normal write operation is performed, the read/write control circuit 51 may generate the active signal ACT and the write control signal WT_CNT which are enabled in response to the write command signal CMD_WT. If the read operation is performed, the read/write control circuit 51 may generate the active signal ACT and the read control signal RD_CNT in response to the read command signal CMD_RD. If the mask write operation is performed, the read/write control circuit 51 may generate the active signal ACT and the read control signal RD_CNT which is enabled and may then generate the active signal ACT and the write control signal WT_CNT after a predetermined period, in response to the write command signal CMD_WT and the internal data mask signal IDM<1:K>. The predetermined period may be set to be a time period from a point of time that the read control signal RD_CNT is generated by the read/write control circuit 51 till a point of time that the write parity signal P_WT<1:P> is generated by the write parity signal generation circuit 16.

The address latch circuit 52 may latch the internal address signal IADD to generate a row address signal ADD_ROW and a column address signal ADD_COL. The address latch circuit 52 may latch addresses sequentially inputted through the internal address signal IADD to sequentially generate the row address signal ADD_ROW and the column address signal ADD_COL. The address latch circuit 52 may generate the row address signal ADD_ROW from some bits among the bits included in the internal address signal IADD and may generate the column address signal ADD_COL from the remaining bits of the internal address signal IADD. In some embodiments, the address latch circuit 52 may decode the internal address signal IADD to generate the row address signal ADD_ROW and the column address signal ADD_COL. Although each of the row address signal ADD_ROW and the column address signal ADD_COL is illustrated as a single signal for the purpose of ease and convenience in explanation, each of the row address signal ADD_ROW and the column address signal ADD_COL may be a signal including a plurality of bits.

The memory bank 53 may include a row control circuit 55, a memory cell array 56 and a column control circuit 57.

The row control circuit 55 may activate a word line (not illustrated) corresponding to the row address signal ADD_ROW in response to the active signal ACT. The memory cell array 56 may include a plurality of memory cells and may output data from memory cells connected to the activated word line (not illustrated). The column control circuit 57 may output data corresponding to the column address signal ADD_COL among the data which are outputted from the memory cell array 56 to a data I/O line LIO_DATA and a parity I/O line LIO_P.

The data transmission control circuit 54 may transmit the write data signal DATA_WT<1:M> and the write parity signal P_WT<1:P> to the data I/O line LIO_DATA and the parity I/O line LIO_P or may output data on the data I/O line LIO_DATA and the parity I/O line LIO_P as the read data signal DATA_RD<1:M> and the read parity signal P_RD<1:P>, in response to the write control signal WT_CNT, the read control signal RD_CNT and the internal data mask signal IDM<1:K>. If the write control signal WT_CNT is enabled, the data transmission control circuit 54 may transmit the first write bit group excluding the second write bit group masked according to the internal data mask signal IDM<1:K> from the bits included in the write data signal DATA_WT<1:M> to the data I/O line LIO_DATA and may also transmit the write parity signal P_WT<1:P> to the parity I/O line LIO_P. If the read control signal RD_CNT is enabled, the data transmission control circuit 54 may output the data on the data I/O line LIO_DATA and the parity I/O line LIO_P as the read data signal DATA_RD<1:M> and the read parity signal P_RD<1:P>.

As described above, in a semiconductor system according to a present embodiment, the write data signal DATA_WT<1:M> may include the first write bit group other than the second write bit group which is masked if the mask write operation is performed. Since the write parity signal P_WT<1:P> may not be generated by only the first write bit group included in the write data signal DATA_WT<1:M>, the second read bit group may be read out from the second storage region corresponding to the second write bit group and the pre-parity signal P_PRE<1:P> may be generated from the first write bit group and the second read bit group. However, if an error occurs in the second read bit group, the pre-parity signal P_PRE<1:P> may have an erroneous logic level. Accordingly, an exclusive OR operation of the pre-parity signal P_PRE<1:P> and the syndrome signal SYN<1:P> may be performed to generate the normal write parity signal P_WT<1:P>. Hence, an embodiment of the present disclosure may independently perform an operation of generating the pre-parity signal P_PRE<1:P> in the pre-parity signal generation circuit 161 and an operation of generating the syndrome signal SYN<1:P> in the data error correction circuit 17. Accordingly, an operation of generating the pre-parity signal P_PRE<1:P> and an operation of generating the syndrome signal SYN<1:P> can be simultaneously performed to prevent occurrence of time delay due to an additional logic operation in the mask write operation. As a result, an operation speed of the semiconductor system may be improved.

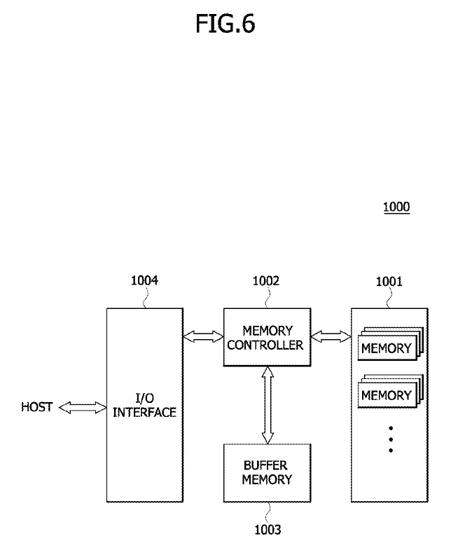

A second semiconductor device or a semiconductor system described with reference to FIGS. 1 to 5 may be applied to an electronic system that includes a memory system, a graphic system, a computing system, a mobile system, or the like. For example, as illustrated in FIG. 6, an electronic system 1000 according an embodiment may include a data storage circuit 1001, a memory controller 1002, a buffer memory 1003, and an input/output (I/O) interface 1004.

The data storage circuit 1001 may store data which are outputted from the memory controller 1002 or may read and output the stored data to the memory controller 1002, according to a control signal generated from the memory controller 1002. The data storage circuit 1001 may include the second semiconductor device 12 illustrated in FIG. 1. The data storage circuit 1001 may include a nonvolatile memory that can retain their stored data even when its power supply is interrupted. The nonvolatile memory may be a flash memory such as a NOR-type flash memory or a NAND-type flash memory, a phase change random access memory (PRAM), a resistive random access memory (RRAM), a spin transfer torque random access memory (STTRAM), a magnetic random access memory (MRAM), or the like.

The memory controller 1002 may receive a command outputted from an external device (e.g., a host device) through the I/O interface 1004 and may decode the command outputted from the host device to control an operation for inputting data into the data storage circuit 1001 or the buffer memory 1003 or for outputting the data stored in the data storage circuit 1001 or the buffer memory 1003. The memory controller 1002 may include the first semiconductor device 11 illustrated in FIG. 1. Although FIG. 6 illustrates the memory controller 1002 with a single block, the memory controller 1002 may include one controller for controlling the data storage circuit 1001 comprised of a nonvolatile memory and another controller for controlling the buffer memory 1003 comprised of a volatile memory.

The buffer memory 1003 may temporarily store the data which are processed by the memory controller 1002. That is, the buffer memory 1003 may temporarily store the data outputted from the data storage circuit 1001 or to be inputted to the data storage circuit 1001. The buffer memory 1003 may store the data, which are outputted from the memory controller 1002, according to a control signal. The buffer memory 1003 may read and output the stored data to the memory controller 1002. The buffer memory 1003 may include a volatile memory such as a dynamic random access memory (DRAM), a mobile DRAM or a static random access memory (SRAM).

The I/O interface 1004 may physically and electrically connect the memory controller 1002 to the external device (i.e., the host). Thus, the memory controller 1002 may receive control signals and data supplied from the external device (i.e., the host) through the I/O interface 1004 and may output the data generated from the memory controller 1002 to the external device (i.e., the host) through the I/O interface 1004. That is, the electronic system 1000 may communicate with the host through the I/O interface 1004. The I/O interface 1004 may include any one of various interface protocols such as a universal serial bus (USB), a multi-media card (MMC), a peripheral component interconnect-express (PCI-E), a serial attached SCSI (SAS), a serial AT attachment (SATA), a parallel AT attachment (PATA), a small computer system interface (SCSI), an enhanced small device interface (ESDI) and an integrated drive electronics (IDE).

The electronic system 1000 may be used as an auxiliary storage device of the host or an external storage device. The electronic system 1000 may include a solid state disk (SSD), a USB memory, a secure digital (SD) card, a mini secure digital (mSD) card, a micro secure digital (micro SD) card, a secure digital high capacity (SDHC) card, a memory stick card, a smart media (SM) card, a multi-media card (MMC), an embedded multi-media card (eMMC), a compact flash (CF) card, or the like.

According to the present disclosure, in the event that a mask write operation is performed, an operation of generating a pre-parity signal from a write data signal and a read data signal and an operation of generating a syndrome signal from the read data signal and a read parity signal may be simultaneously performed to prevent occurrence of time delay due to an additional logic operation during the mask write operation. Hence, it may be possible to improve an operation speed of a semiconductor device.

A semiconductor device comprises a memory core circuit configured to generate a read data signal and a read parity signal from a storage region corresponding to an internal address signal, if a mask write operation is performed, a write parity signal generation circuit configured to generate a pre-parity signal from a write data signal and the read data signal, if the mask write operation is performed, and a data error correction circuit configured to generate a syndrome signal from the read data signal and the read parity signal, if the mask write operation is performed.

Wherein the generation of the pre-parity signal and the syndrome signal are simultaneously performed.

Wherein the semiconductor device is configured to independently perform the generation of the pre-parity signal with the write parity signal generation circuit and the generation of the syndrome signal with the data error correction circuit.

Wherein the write data signal includes first and second write bit groups; wherein the read data signal includes first and second read bit groups; and wherein the pre-parity signal is generated from the first write bit group and the second read bit group.

Wherein the syndrome signal includes information on a position of an erroneous bit among bits included in the read data signal.

A semiconductor device comprises a pre-parity signal generation circuit configured to generate a pre-parity signal from a write data signal and a read data signal, if a mask write operation is performed, and a data error correction circuit configured to generate a syndrome signal from the read data signal and a read parity signal, if the mask write operation is performed,

Wherein the generation of the pre-parity signal and the syndrome signal are performed concurrently.

Wherein the write data signal includes first and second write bit groups, wherein the read data signal includes first and second read bit groups, and wherein the pre-parity signal is generated from the first write bit group and the second read bit group.

Wherein the syndrome signal includes information on a position of an erroneous bit among bits included in the read data signal.

A write parity signal generation circuit comprises a pre-parity signal generation circuit configured to generate a pre-parity signal from a write data signal and a read data signal, based on performance of a mask write operation, and a logic arithmetic circuit configured to generate a write parity signal from the pre-parity signal and a syndrome signal, wherein the syndrome signal is received externally from the write parity signal generation circuit.

Wherein the generation of the pre-parity signal and a generation of the syndrome signal are performed concurrently.

Wherein the syndrome signal includes information on a position of an erroneous bit among bits included in the read data signal.

What is claimed is:

1. A semiconductor device comprising:
a write parity signal generation circuit configured to generate a pre-parity signal from a write data signal and a read data signal and configured to generate a write parity signal from the pre-parity signal and a syndrome signal based on a control signal, if a mask write operation is performed; and
a data error correction circuit configured to generate the syndrome signal from the read data signal and a read parity signal and configured to generate the control signal according to an error position of the read data signal included in the syndrome signal and a masked position of the write data signal included in an internal data mask signal.

2. The device of claim 1,
wherein the write data signal includes first and second write bit groups;
wherein the read data signal includes first and second read bit groups; and
wherein the pre-parity signal is generated from the first write bit group and the second read bit group.

3. The device of claim 2, wherein the second write bit group includes bits which are masked during the mask write operation.

4. The device of claim 2, wherein the second read bit group includes bits which are outputted from a storage region corresponding to the second write bit group.

5. The device of claim 2, wherein the control signal is enabled if an erroneous bit is included in the second read bit group of the read data signal.

6. The device of claim 1, wherein the syndrome signal includes information on a position of an erroneous bit among bits included in the read data signal.

7. The device of claim 1, wherein the write parity signal generation circuit performs an exclusive OR operation of the pre-parity signal and the syndrome signal to generate the write parity signal based on the control signal.

8. The device of claim 1, wherein an operation of generating the pre-parity signal and an operation of generating the syndrome signal are simultaneously performed.

9. The device of claim 2, wherein the write parity signal generation circuit includes:
a pre-parity signal generation circuit configured to generate the pre-parity signal from the first write bit group and the second read bit group based on the internal data mask signal; and
a logic arithmetic circuit configured to generate the write parity signal from the pre-parity signal and the syndrome signal based on the control signal.

10. The device of claim 9, wherein the pre-parity signal generation circuit includes:
a data merging circuit configured to merge the first write bit group and the second read bit group to generate a merging data signal based on the internal data mask signal; and
a pre-parity signal arithmetic circuit configured to generate the pre-parity signal from the merging data signal.

11. The device of claim 9, wherein the logic arithmetic circuit includes:
a first logic circuit configured to buffer the syndrome signal to generate a parity correction control signal based on the control signal; and
a second logic circuit configured to perform an exclusive OR operation of the pre-parity signal and the parity correction control signal to generate the write parity signal.

12. The device of claim 1, wherein the data error correction circuit includes:
a syndrome signal arithmetic circuit configured to generate the syndrome signal based on the read data signal and the read parity signal;
an error position decoder configured to decode the syndrome signal to generate an error position signal; and
a control signal generation circuit configured to compare the error position signal with the internal data mask signal to generate the control signal.

13. The device of claim 12, wherein the data error correction circuit further includes a correction data signal generation circuit configured to correct an error of the read data signal to generate a correction data signal based on the error position signal, if a read operation is performed.

14. The device of claim 1, further comprising a memory core circuit configured to output the read data signal and the read parity signal and configured to store the write data signal and the write parity signal therein after a predetermined period from a point of time that the read data signal and the read parity signal are outputted, based on a write command signal, an internal address signal and the internal data mask signal, if the mask write operation is performed.

15. The device of claim 14, wherein the predetermined period is a time period from a point of time that the read data signal and the read parity signal are outputted from the memory core circuit till a point of time that the write parity signal is generated.

16. A semiconductor device comprising:
a memory core circuit configured to generate a read data signal and a read parity signal from a storage region corresponding to an internal address signal based on a write command signal and an internal data mask signal, if a mask write operation is performed; and
a write parity signal generation circuit configured to generate a pre-parity signal from a write data signal and the read data signal and configured to generate a write parity signal from the pre-parity signal and a syndrome signal based on a control signal, if the mask write operation is performed.

17. The device of claim 16,
wherein the write data signal includes first and second write bit groups;
wherein the read data signal includes first and second read bit groups; and
wherein the pre-parity signal is generated from the first write bit group and the second read bit group.

18. The device of claim 17, wherein the second write bit group includes bits which are masked during the mask write operation.

19. The device of claim 17, wherein the second read bit group includes bits which are outputted from a storage region corresponding to the second write bit group.

20. The device of claim 17, wherein the control signal is enabled if an erroneous bit is included in the second read bit group of the read data signal.

21. The device of claim 16, wherein the syndrome signal includes information on a position of an erroneous bit among bits included in the read data signal.
